(19) United States
(12) Patent Application Publication
(10) Pub. No.: US 2025/0062185 A1
(43) Pub. Date: Feb. 20, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Ling CHEN, Taichung City (TW); Kuan-Wei CHUANG, Taichung City (TW)

(21) Appl. No.: 18/538,415

(22) Filed: Dec. 13, 2023

(30) Foreign Application Priority Data
Aug. 15, 2023 (TW) 112130667

(51) Int. Cl. H01L 23/373; H01L 23/00; H01L 23/29; H01L 23/31; H01L 25/065

(52) U.S. Cl. CPC H01L 23/3731; H01L 23/293; H01L 23/3121; H01L 24/05; H01L 24/29; H01L 25/0652; H01L 2224/05005; H01L 2224/05023; H01L 2224/29006; H01L 2224/29021; H01L 2224/2919; H01L 2924/182; H01L 2924/183; H01L 2924/3511

(57) ABSTRACT

An electronic package and a manufacturing method thereof are provided, in which an offset suppression layer is formed on a carrier, a first electronic element and a second electronic element are respectively disposed on the offset suppression layer, and an encapsulant is formed on the offset suppression layer to respectively cover the first electronic element and the second electronic element. The offset suppression layer effectively suppresses or prevents possible offset caused by the encapsulant to the first electronic element and the second electronic element, thereby avoiding yield loss of the semiconductor package.

### BACKGROUND

### 1. Technical Field

The present disclosure relates to a package structure, and more particularly, to an electronic package with an offset suppression layer and a manufacturing method thereof.

### 2. Description of Related Art

When the semiconductor chip on the glass substrate is performed with high-temperature molding or curing process of the encapsulant, since the coefficient of thermal expansion (CTE) of the glass substrate is much less than the coefficient of thermal expansion of the encapsulant (for instance, the coefficient of thermal expansion of the glass substrate and the coefficient of thermal expansion of the encapsulant are 0.3 ppm/K and 7 ppm/K respectively), the glass substrate will expand outward when the encapsulant is heated and shrink inward when the encapsulant is cooled, causing the semiconductor chip to offset by an outward expansion amount as the glass substrate expands outward and offset by an inward shrinkage amount as the glass substrate shrinks inward.

Furthermore, since the coefficient of thermal expansion of the glass substrate (such as 0.3 ppm/K) and the coefficient of thermal expansion of the encapsulant (such as 7 ppm/K) do not belong to the same grade, the outward expansion amount and inward shrinkage amount of the semiconductor chip on the glass substrate are not the same or are largely different, so that the semiconductor chip will offset (for example, the semiconductor chip cannot back to the original position), thereby causing the yield loss of the semiconductor package.

FIG. 1A to FIG. 1C are schematic cross-sectional views illustrating a method of manufacturing a conventional semiconductor package 1.

As shown in FIG. 1A, first, two semiconductor chips 12 are respectively disposed on a glass substrate 10 having a first length L1 via an adhesive layer 11. Each of the semiconductor chips 12 can have an active surface 12a, an inactive surface 12b and a side surface 12c. A plurality of electrode pads 12d may be formed on the active surface 12a of the semiconductor chip 12, and an initial position of the semiconductor chip 12 (such as the side surface 12c) is a first position P1.

As shown in FIG. 1B, when the semiconductor chip 12 on the glass substrate 10 is performed with high-temperature molding or curing process of an encapsulant 13 (e.g., a packaging colloid), the glass substrate 10 will expand outward from the first length L1 (see FIG. 1A) to a second length L2 according to an outward expansion direction A1 when the encapsulant 13 is heated, and the semiconductor chip 12 will offset from the first position P1 (initial position) to a second position P2 as the outward expansion of the glass substrate 10, and the first position P1 and the second position P2 of the semiconductor chip 12 differ by an outward expansion amount B1 (such as the first offset distance).

As shown in FIG. 1C, when the encapsulant 13 is cooled, the glass substrate 10 will shrink inward from the second length L2 (see FIG. 1B) to a third length L3 according to a contraction direction A2 (e.g., an inward shrinkage direction), and the semiconductor chip 12 will offset from the second position P2 to a third position P3 as the inward shrinkage of the glass substrate 10, and the second position P2 and the third position P3 of the semiconductor chip 12 differ by an inward shrinkage amount B2 (such as the second offset distance).

In other words, in the conventional semiconductor package 1, the coefficient of thermal expansion of the glass substrate 10 (such as 0.3 ppm/K) is much less than the coefficient of thermal expansion of the encapsulant 13 (such as 7 ppm/K), such that the coefficient of thermal expansion of the glass substrate 10 and the coefficient of thermal expansion of the encapsulant 13 do not belong to the same grade. As a result, the outward expansion amount B1 and the inward shrinkage amount B2 of the semiconductor chip 12 on the glass substrate 10 are not the same or are largely different, so that the semiconductor chip 12 offsets (for example, the semiconductor chip 12 cannot back to the initial position or the first position P1), thereby causing the yield loss of the semiconductor package 1.

Therefore, there is a need for a solution that addresses the aforementioned shortcomings in the prior art.

### SUMMARY

In view of the aforementioned shortcomings of the prior art, the present disclosure provides an electronic package, which comprises: a carrier; an offset suppression layer having a first surface and a second surface opposing the first surface, wherein the offset suppression layer is formed on the carrier via the second surface; a first electronic element and a second electronic element disposed on the first surface of the offset suppression layer; and an encapsulant formed on the first surface of the offset suppression layer and covering the first electronic element and the second electronic element, wherein the offset suppression layer suppresses an offset of the first electronic element and the second electronic element.

The present disclosure also provides a method of manufacturing an electronic package, the method comprises: forming an offset suppression layer having a first surface and a second surface opposing the first surface on a carrier via the second surface; disposing a first electronic element and a second electronic element on the first surface of the offset suppression layer; and forming an encapsulant on the first surface of the offset suppression layer to cover the first electronic element and the second electronic element, wherein the offset suppression layer suppresses an offset of the first electronic element and the second electronic element.

In the aforementioned electronic package and method, the electronic package may also comprise a first adhesive layer and a second adhesive layer, wherein the first electronic element and the second electronic element are bonded to the first surface of the offset suppression layer via the first adhesive layer and the second adhesive layer respectively.

In the aforementioned electronic package and method, the offset suppression layer is made of polyimide material, and the offset suppression layer made of polyimide material is formed or coated on the carrier. Meanwhile, a coefficient of thermal expansion of the offset suppression layer and a coefficient of thermal expansion of the encapsulant are equal or close and belong to a same grade.

In the aforementioned electronic package and method, a thickness of the offset suppression layer is between 40 microns and 70 microns, or a ratio of the thickness of the offset suppression layer to a thickness of the encapsulant is 1.75:1, or a thickness of the first electronic element and a thickness of the second electronic element are less than 60 microns.

In the aforementioned electronic package and method, the first surface of the offset suppression layer is a rough surface, and the rough surface of the offset suppression layer is bonded to the encapsulant covering the first electronic element and the second electronic element.

In the aforementioned electronic package and method, the first surface of the offset suppression layer is formed with a plurality of convex portions and a plurality of recessed portions, and the plurality of convex portions and the plurality of recessed portions of the first surface of the offset suppression layer are bonded to the encapsulant covering the first electronic element and the second electronic element.

In the aforementioned electronic package and method, the first surface of the offset suppression layer is formed with a first recessed portion and a second recessed portion, and the first electronic element and the second electronic element are respectively bonded to the first recessed portion and the second recessed portion of the first surface of the offset suppression layer.

As can be understood from the above, in the electronic package and the manufacturing method thereof of the present disclosure, the offset suppression layer is formed on the carrier, and the first electronic element and the second electronic element are respectively disposed on the offset suppression layer, and then the encapsulant is formed on the offset suppression layer to cover the first electronic element and the second electronic element, so that the offset suppression layer can effectively suppress or prevent the possible offset caused by the encapsulant to the first electronic element and the second electronic element, thereby avoiding the yield loss of the semiconductor package.

Meanwhile, in the present disclosure, the coefficient of thermal expansion of the offset suppression layer and the coefficient of thermal expansion of the encapsulant are equal or close, so that the outward expansion amount of the first electronic element and the second electronic element on the offset suppression layer when the encapsulant is heated is equal or close to the inward shrinkage amount when the encapsulant is cooled. In this way, the offset suppression effect of the first electronic element and the second electronic element on the offset suppression layer during the molding or curing process of the encapsulant can be achieved, thereby avoiding the offset of the first electronic element and the second electronic element caused by a large difference in coefficient of thermal expansion of different materials or the coefficient of thermal expansion of the first electronic element and the coefficient of thermal expansion of the second electronic element not belonging to the same grade.

Furthermore, the thickness of the offset suppression layer of the present disclosure can be between 40 microns and 70 microns (μm), or the ratio of the thickness of the offset suppression layer to the thickness of the encapsulant can be about 1.75:1, or the thickness of the first electronic element and the thickness of the second electronic element can be less than 60 microns, so that the offset suppression layer can provide the best offset suppression effect to the first electronic element and the second electronic element.

### BRIEF DESCRIPTION OF THE DRAWINGS

FIG. 1A to FIG. 1C are schematic cross-sectional views illustrating a method of manufacturing a conventional semiconductor package.

FIG. 2A to FIG. 2C are schematic cross-sectional views illustrating a method of manufacturing an electronic package of the present disclosure.

FIG. 3A and FIG. 3B are schematic cross-sectional views showing different embodiments of the electronic package of the present disclosure respectively.

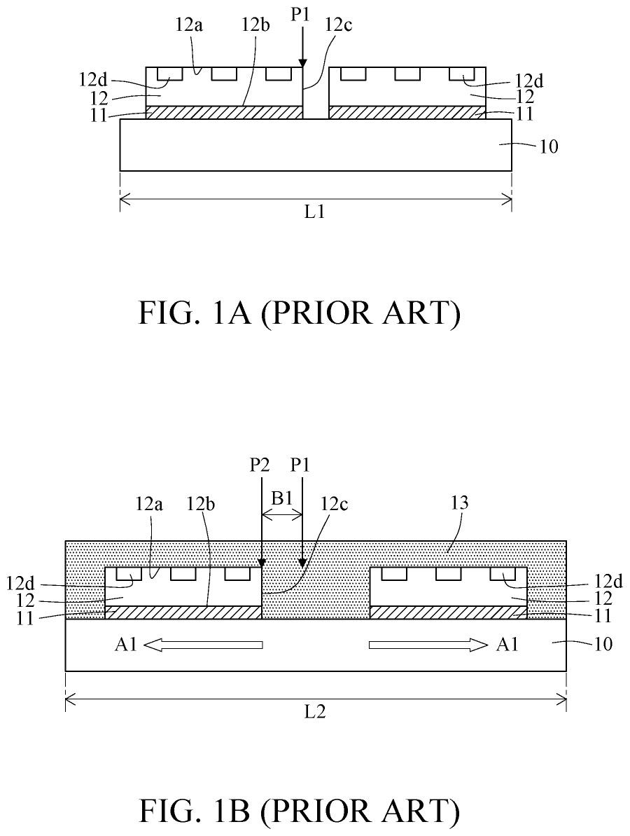

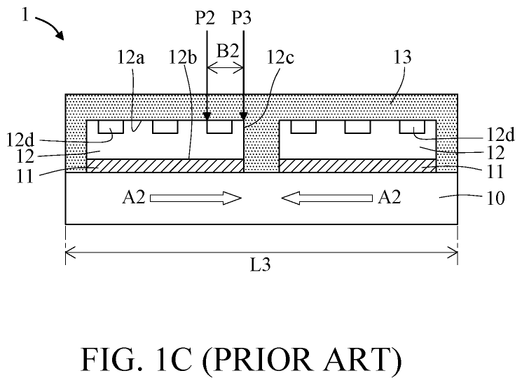

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “below,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

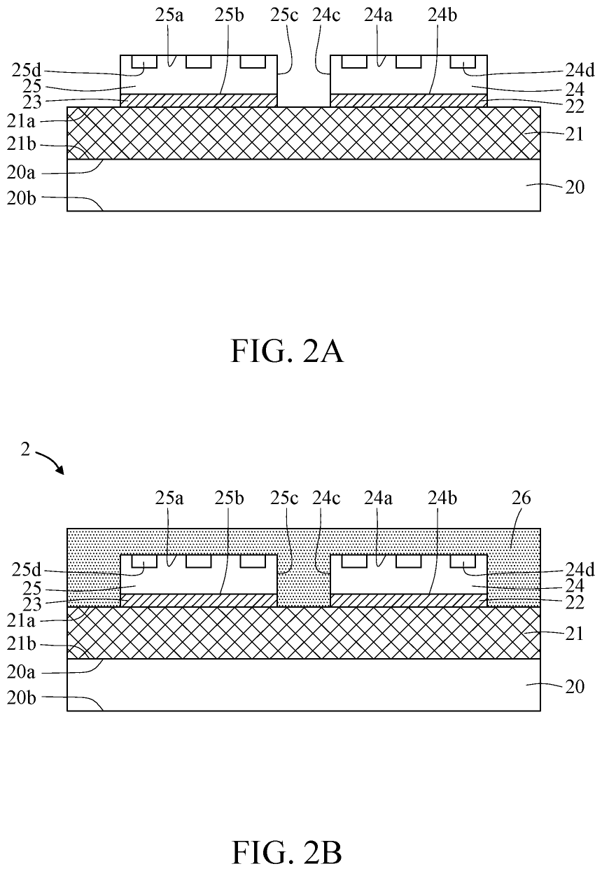

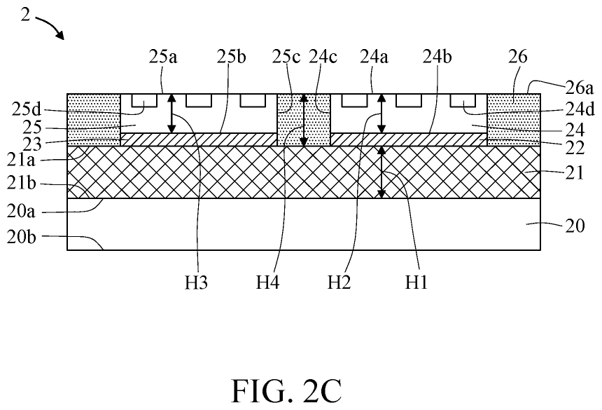

FIG. 2A to FIG. 2C are schematic cross-sectional views illustrating a method of manufacturing an electronic package 2 of the present disclosure. Meanwhile, “at least one” in the present disclosure represents one or more (such as one, two, three, four, or more than four), and “plurality” represents two or more (such as two, three, four, ten, or more than ten).

As shown in FIG. 2A, a carrier 20 having a first side 20a (such as an upper side) and a second side 20b (such as a lower side) opposing the first side 20a is provided, so that an offset suppression layer 21 having a first surface 21a (such as an upper surface) and a second surface 21b (such as a lower surface) opposing the first surface 21a is formed on the first side 20a of the carrier 20 via the second surface 21b, and then at least one first electronic element 24 and at least one second electronic element 25 are respectively disposed on different positions on the first surface 21a of the offset suppression layer 21. For example, the first electronic element 24 and the second electronic element 25 are bonded to different positions on the first surface 21a of the offset suppression layer 21 via a first adhesive layer 22 and a second adhesive layer 23 respectively.

In one embodiment, the carrier 20 can be a glass substrate, a semiconductor substrate, a silicon substrate, etc., and the carrier 20 can also be a carrier unit of other types that can carry the first electronic element 24 and the second electronic element 25, such as a wafer, a silicon interposer, or a board of other types, etc., but the present disclosure is not limited to as such.

In one embodiment, the first electronic element 24 or the second electronic element 25 can be an active element, a passive element, or a combination of the active element and the passive element. For example, the active element is a semiconductor chip, and the passive element is a resistor, a capacitor, or an inductor.

In one embodiment, the first electronic element 24 can be a semiconductor chip and has an active surface 24a, an inactive surface 24b opposing the active surface 24a, and side surfaces 24c connecting the active surface 24a and the inactive surface 24b. Further, a plurality of electrode pads 24d may be formed at the active surface 24a of the first electronic element 24. Meanwhile, the second electronic element 25 can be another semiconductor chip and has an active surface 25a, an inactive surface 25b opposing the active surface 25a, and side surfaces 25c connecting the active surface 25a and the inactive surface 25b. In addition, a plurality of electrode pads 25d may be formed at the active surface 25a of the second electronic element 25.

As shown in FIG. 2B, the first electronic element 24 and the second electronic element 25 on the offset suppression layer 21 are performed with molding and curing processes of an encapsulant 26 (e.g., a packaging colloid), and the encapsulant 26 is formed on the first surface 21a of the offset suppression layer 21 to respectively cover the first electronic element 24 and the second electronic element 25.

In one embodiment, the encapsulant 26 is formed on the first surface 21a of the offset suppression layer 21, so that the first adhesive layer 22 (such as the side surfaces of the first adhesive layer 22), the second adhesive layer 23 (such as the side surfaces of the second adhesive layer 23), the first electronic element 24 (such as the side surfaces 24c of the first electronic element 24) and the second electronic element 25 (such as the side surfaces 25c of the second electronic element 25) are covered by the encapsulant 26 respectively.

In one embodiment, the encapsulant 26 may be further formed on the active surface 24a of the first electronic element 24 and the active surface 25a of the second electronic element 25 to cover the plurality of electrode pads 24d and the plurality of electrode pads 25d.

In one embodiment, the offset suppression layer 21 can be made of polyimide (PI) material, wherein the offset suppression layer 21 made of polyimide material can be formed or coated on the first side 20a of the carrier 20, and the coefficient of thermal expansion of the offset suppression layer 21 (e.g., 4 ppm/K) can be equal or close to the coefficient of thermal expansion of the encapsulant 26 (e.g., 7 ppm/K), so that the coefficient of thermal expansion of the offset suppression layer 21 is in the same grade as the coefficient of thermal expansion of the encapsulant 26.

In one embodiment, the coefficient of thermal expansion of the offset suppression layer 21 (e.g., 4 ppm/K) and the coefficient of thermal expansion of the encapsulant 26 (e.g., 7 ppm/K) are equal or close, so that the “outward expansion amount” of the first electronic element 24 and the second electronic element 25 on the offset suppression layer 21 when the encapsulant 26 is heated and the “inward shrinkage amount” of the first electronic element 24 and the second electronic element 25 on the offset suppression layer 21 when the encapsulant 26 is cooled are equal or close. In this way, the present disclosure can achieve the offset suppression effect of the first electronic element 24 and the second electronic element 25 on the offset suppression layer 21 during the molding or curing process of the encapsulant 26, thereby avoiding the offset of the first electronic element 24 and the second electronic element 25 caused by a large difference in coefficient of thermal expansion of different materials or the coefficient of thermal expansion of the first electronic element 24 and the coefficient of thermal expansion of the second electronic element 25 not belonging to the same grade.

As shown in FIG. 2C, in one embodiment, part of the encapsulant 26 can be further removed by thinning method such as grinding, etching, or photolithography, so that the plurality of electrode pads 24d on the active surface 24a of the first electronic element 24 and the plurality of electrode pads 25d on the active surface 25a of the second electronic element 25 are exposed from a surface 26a (such as an upper surface) of the encapsulant 26.

In one embodiment, the surface 26a (such as the upper surface) of the encapsulant 26 can be coplanar with the active surface 24a of the first electronic element 24 and/or the active surface 25a of the second electronic element 25, so that the surface 26a of the encapsulant 26 is flush with the active surface 24a of the first electronic element 24 and/or the active surface 25a of the second electronic element 25, but the present disclosure is not limited to as such.

In one embodiment, a thickness H1 of the offset suppression layer 21 may be between 40 microns (μm) and 70 microns, so that the offset suppression layer 21 can provide the best offset suppression effect to the first electronic element 24 and the second electronic element 25.

In one embodiment, the thickness H1 of the offset suppression layer 21 and a thickness H4 of the encapsulant 26 can be selected according to the different requirements of a thickness H2 of the first electronic element 24 and a thickness H3 of the second electronic element 25. For example, the ratio of the thickness H1 of the offset suppression layer 21 to the thickness H4 of the encapsulant 26 may be about 1.75:1, i.e., the thickness H1 of the offset suppression layer 21 is about 1.75 times the thickness H4 of the encapsulant 26, so that the offset suppression layer 21 can provide the best offset suppression effect to the first electronic element 24 and the second electronic element 25.

In one embodiment, the thickness H2 of the first electronic element 24 and the thickness H3 of the second electronic element 25 can both be less than 60 microns, so that the offset suppression layer 21 can provide the best offset suppression effect to the first electronic element 24 and the second electronic element 25.

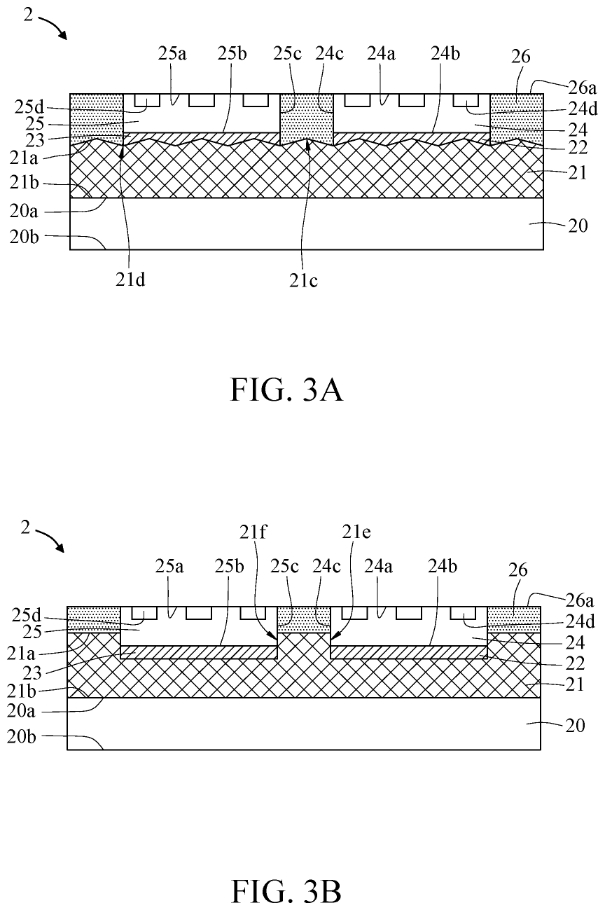

FIG. 3A and FIG. 3B are schematic cross-sectional views showing different embodiments of the electronic package 2 of the present disclosure respectively.

As shown in FIG. 3A, the first surface 21a (such as the upper surface) of the offset suppression layer 21 of this embodiment can be a rough surface (such as a non-flat surface or a non-smooth surface), and the rough surface of the offset suppression layer 21 can be respectively bonded to the first adhesive layer 22 and the second adhesive layer 23 and can also be bonded to the encapsulant 26 covering the first electronic element 24 and the second electronic element 25. Accordingly, the present disclosure can improve the bonding strength of the offset suppression layer 21 with the first adhesive layer 22, the second adhesive layer 23 and the encapsulant 26 respectively by the rough surface of the offset suppression layer 21, and the first electronic element 24 and the second electronic element 25 on the rough surface of the offset suppression layer 21 are also less likely to be affected by the molding or curing process of the encapsulant 26, thereby preventing the offset of the first electronic element 24 and the second electronic element 25.

For example, the first surface 21a (such as the upper surface) of the offset suppression layer 21 may be formed with a plurality of convex portions 21c (such as bumps) and a plurality of recessed portions 21d (such as recesses). The plurality of convex portions 21c and the plurality of recessed portions 21d of the offset suppression layer 21 can be bonded to the first adhesive layer 22 and the second adhesive layer 23, and can also be bonded to the encapsulant 26 covering the first electronic element 24 and the second electronic element 25.

As shown in FIG. 3B, at least one first recessed portion 21e (e.g., a first recess) and at least one second recessed portion 21f (e.g., a second recess) may be formed on the first surface 21a (such as the upper surface) of the offset suppression layer 21 of this embodiment to accommodate the at least one first electronic element 24 and the at least one second electronic element 25 respectively, and the first electronic element 24 and the second electronic element 25 can be bonded to the first recessed portion 21e and the second recessed portion 21f of the first surface 21a of the offset suppression layer 21 by the first adhesive layer 22 and the second adhesive layer 23 respectively. Accordingly, in the present disclosure, the first electronic element 24 on the first adhesive layer 22 and the second electronic element 25 on the second adhesive layer 23 can be effectively fixed (restricted) to the first recessed portion 21e and the second recessed portion 21f of the first surface 21a of the offset suppression layer 21, respectively, and the first electronic element 24 and the second electronic element 25 on the first recessed portion 21e and the second recessed portion 21f of the first surface 21a of the offset suppression layer 21 are also less likely to be affected by the molding or curing process of the encapsulant 26, thereby preventing the offset of the first electronic element 24 and the second electronic element 25.

For example, the first adhesive layer 22 and the inactive surface 24b of the first electronic element 24 can be respectively located in the first recessed portion 21e of the offset suppression layer 21, and part of the side surface 24c of the first electronic element 24 can be directly in contact with the side wall of the first recessed portion 21e of the offset suppression layer 21. Meanwhile, the second adhesive layer 23 and the inactive surface 25b of the second electronic element 25 can be located in the second recessed portion 21f of the offset suppression layer 21 respectively, and part of the side surface 25c of the second electronic element 25 can be directly in contact with the side wall of the second recessed portion 21f of the offset suppression layer 21.

The present disclosure further provides an electronic package 2, comprising: a carrier 20; an offset suppression layer 21 formed on the carrier 20, and the offset suppression layer 21 having a first surface 21a and a second surface 21b opposing the first surface 21a; a first electronic element 24 and a second electronic element 25 respectively disposed on the first surface 21a of the offset suppression layer 21; and an encapsulant 26 formed on the first surface 21a of the offset suppression layer 21 and covering the first electronic element 24 and the second electronic element 25 respectively, wherein the offset suppression layer 21 suppresses an offset of the first electronic element 24 and the second electronic element 25.

In one embodiment, the electronic package 2 may also comprise a first adhesive layer 22 and a second adhesive layer 23, wherein the first electronic element 24 and the second electronic element 25 are bonded to the first surface 21a of the offset suppression layer 21 via the first adhesive layer 22 and the second adhesive layer 23 respectively.

In one embodiment, the offset suppression layer 21 can be made of polyimide material, and the offset suppression layer 21 made of polyimide material is formed or coated on a first side 20a of the carrier 20.

In one embodiment, a coefficient of thermal expansion of the offset suppression layer 21 and a coefficient of thermal expansion of the encapsulant 26 are equal or close and belong to the same grade.

In one embodiment, a thickness H1 of the offset suppression layer 21 is between 40 microns and 70 microns.

In one embodiment, a ratio of the thickness H1 of the offset suppression layer 21 to a thickness H4 of the encapsulant 26 is about 1.75:1, that is, the thickness H1 of the offset suppression layer 21 is about 1.75 times the thickness H4 of the encapsulant 26.

In one embodiment, a thickness H2 of the first electronic element 24 and a thickness H3 of the second electronic element 25 are both less than 60 microns.

In one embodiment, the first surface 21a of the offset suppression layer 21 is a rough surface, and the rough surface of the offset suppression layer 21 is bonded to the encapsulant 26 covering the first electronic element 24 and the second electronic element 25.

In one embodiment, the first surface 21a of the offset suppression layer 21 is formed with a plurality of convex portions 21c and a plurality of recessed portions 21d, and the plurality of convex portions 21c and the plurality of recessed portions 21d of the first surface 21a of the offset suppression layer 21 are bonded to the encapsulant 26 covering the first electronic element 24 and the second electronic element 25.

In one embodiment, the first surface 21a of the offset suppression layer 21 is formed with a first recessed portion 21e and a second recessed portion 21f, and the first electronic element 24 and the second electronic element 25 are bonded to the first recessed portion 21e and the second recessed portion 21f of the first surface 21a of the offset suppression layer 21 respectively.

In view of the above, the electronic package and the method thereof of the present disclosure have at least the following features, advantages, or technical effects.

1. In the present disclosure, when the first electronic element and the second electronic element are performed with the molding or curing process of the encapsulant, the encapsulant can be formed on the offset suppression layer to cover the first electronic element and the second electronic element respectively, so that the offset suppression layer effectively suppresses or prevents the possible offset caused by the encapsulant to the first electronic element and the second electronic element, thereby avoiding yield loss of the semiconductor package.

2. In the present disclosure, the coefficient of thermal expansion of the offset suppression layer and the coefficient of thermal expansion of the encapsulant are equal or close, so that the outward expansion amount of the first electronic element and the second electronic element on the offset suppression layer when the encapsulant is heated is equal or close to the inward shrinkage amount when the encapsulant is cooled. In this way, the offset suppression effect of the first electronic element and the second electronic element on the offset suppression layer during the molding or curing process of the encapsulant can be achieved, thereby avoiding the offset of the first electronic element and the second electronic element caused by a large difference in coefficient of thermal expansion of different materials or the coefficient of thermal expansion of the first electronic element and the coefficient of thermal expansion of the second electronic element not belonging to the same grade.

3. The thickness of the offset suppression layer of the present disclosure can be between 40 microns and 70 microns, or the ratio of the thickness of the offset suppression layer to the thickness of the encapsulant can be about 1.75:1, or the thickness of the first electronic element and the thickness of the second electronic element can be less than 60 microns, so that the offset suppression layer can provide the best offset suppression effect to the first electronic element and the second electronic element.

4. The first surface of the offset suppression layer of the present disclosure can be a rough surface (such as a non-flat surface or a non-smooth surface), so that the bonding strength of the offset suppression layer with the encapsulant is improved by the rough surface, and the first electronic element and the second electronic element on the rough surface of the offset suppression layer are also less likely to be affected by the molding or curing process of the encapsulant, thereby preventing the offset of the first electronic element and the second electronic element.

5. The first surface of the offset suppression layer of the present disclosure can be formed with a plurality of convex portions and a plurality of recessed portions, so that the bonding strength of the offset suppression layer with the encapsulant is improved by the plurality of convex portions and the plurality of recessed portions, and also the first electronic element and the second electronic element on the plurality of convex portions and the plurality of recessed portions of the offset suppression layer are less likely to be affected by the molding or curing process of the encapsulant, thereby preventing the offset of the first electronic element and the second electronic element.

6. The first surface of the offset suppression layer of the present disclosure can be formed with a first recessed portion and a second recessed portion to respectively accommodate the first electronic element and the second electronic element to facilitate fixing (restricting) the first electronic element and the second electronic element at the first recessed portion and the second recessed portion on the first surface of the offset suppression layer, so that the first electronic element and the second electronic element are less likely to be affected by the molding or curing process of the encapsulant, thereby preventing the offset of the first electronic element and the second electronic element.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier;
an offset suppression layer having a first surface and a second surface opposing the first surface, wherein the offset suppression layer is formed on the carrier via the second surface;
a first electronic element and a second electronic element disposed on the first surface of the offset suppression layer; and
an encapsulant formed on the first surface of the offset suppression layer and covering the first electronic element and the second electronic element, wherein the offset suppression layer suppresses an offset of the first electronic element and the second electronic element.

2. The electronic package of claim 1, further comprising a first adhesive layer and a second adhesive layer, wherein the first electronic element and the second electronic element are bonded to the first surface of the offset suppression layer via the first adhesive layer and the second adhesive layer respectively.

3. The electronic package of claim 1, wherein the offset suppression layer is made of polyimide material.

4. The electronic package of claim 1, wherein a coefficient of thermal expansion of the offset suppression layer and a coefficient of thermal expansion of the encapsulant are equal or close and belong to a same grade.

5. The electronic package of claim 1, wherein a thickness of the offset suppression layer is between 40 microns and 70 microns.

6. The electronic package of claim 1, wherein a ratio of a thickness of the offset suppression layer to a thickness of the encapsulant is 1.75:1.

7. The electronic package of claim 1, wherein a thickness of the first electronic element and a thickness of the second electronic element are less than 60 microns.

8. The electronic package of claim 1, wherein the first surface of the offset suppression layer is a rough surface, and the rough surface of the offset suppression layer is bonded to the encapsulant covering the first electronic element and the second electronic element.

9. The electronic package of claim 1, wherein the first surface of the offset suppression layer is formed with a plurality of convex portions and a plurality of recessed portions, and the plurality of convex portions and the plurality of recessed portions of the first surface of the offset suppression layer are bonded to the encapsulant covering the first electronic element and the second electronic element.

10. The electronic package of claim 1, wherein the first surface of the offset suppression layer is formed with a first recessed portion and a second recessed portion, and the first electronic element and the second electronic element are respectively bonded to the first recessed portion and the second recessed portion of the first surface of the offset suppression layer.

11. A method of manufacturing an electronic package, comprising:
forming an offset suppression layer having a first surface and a second surface opposing the first surface on a carrier via the second surface;
disposing a first electronic element and a second electronic element on the first surface of the offset suppression layer; and
forming an encapsulant on the first surface of the offset suppression layer to cover the first electronic element and the second electronic element, wherein the offset suppression layer suppresses an offset of the first electronic element and the second electronic element.

12. The method of claim 11, further comprising bonding the first electronic element and the second electronic element onto the first surface of the offset suppression layer via a first adhesive layer and a second adhesive layer respectively.

13. The method of claim 11, wherein the offset suppression layer is made of polyimide material.

14. The method of claim 11, wherein a coefficient of thermal expansion of the offset suppression layer and a coefficient of thermal expansion of the encapsulant are equal or close and belong to a same grade.

15. The method of claim 11, wherein a thickness of the offset suppression layer is between 40 microns and 70 microns.

16. The method of claim 11, wherein a ratio of a thickness of the offset suppression layer to a thickness of the encapsulant is 1.75:1.

17. The method of claim 11, wherein a thickness of the first electronic element and a thickness of the second electronic element are less than 60 microns.

18. The method of claim 11, wherein the first surface of the offset suppression layer is a rough surface, and the rough surface of the offset suppression layer is bonded to the encapsulant covering the first electronic element and the second electronic element.

19. The method of claim 11, wherein the first surface of the offset suppression layer is formed with a plurality of convex portions and a plurality of recessed portions, and the plurality of convex portions and the plurality of recessed portions of the first surface of the offset suppression layer are bonded to the encapsulant covering the first electronic element and the second electronic element.

20. The method of claim 11, wherein the first surface of the offset suppression layer is formed with a first recessed portion and a second recessed portion, and the first electronic element and the second electronic element are respectively bonded to the first recessed portion and the second recessed portion of the first surface of the offset suppression layer.
